(19) United States
(12) Patent Application Publication
(10) Pub. No.: US 2006/0144695 A1
(43) Pub. Date: Jul. 6, 2006

(54) SPUTTERING PROCESS FOR DEPOSITING INDIUM TIN OXIDE AND METHOD FOR FORMING INDIUM TIN OXIDE LAYER

(76) Inventors: Yu-Chou Lee, TAIPEI (TW); Tsung-Chi Cheng, TAICHUNG CITY (TW); Hung-I Hsu, MIAOLI COUNTY (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,189

(22) Filed: Mar. 24, 2005

(30) Foreign Application Priority Data
Jan. 3, 2005 (TW) 94100026

(51) Int. Cl. C23C 14/00

(52) U.S. Cl. 204/192.15

(57) ABSTRACT

A sputtering process of indium tin oxide (ITO) is provided. The sputtering process includes the following steps. First, a substrate is moved into a reaction chamber, wherein an ITO target is disposed inside the reaction chamber. Then, a plasma gas and a reaction gas are provided into the reaction chamber to form an ITO layer on the substrate. The reaction gas comprises at least hydrogen having a volume ratio of 1%˜4% based on the total gas volume in the reaction chamber. Furthermore, a method of forming an indium tin oxide layer is also provided.

### CROSS-REFERENCE TO RELATED APPLICATION

This application claims the priority benefit of Taiwan application serial no. 94100026, filed Jan. 3, 2005.

### BACKGROUND OF THE INVENTION

1. Field of the Invention

The present invention relates to a sputtering process for depositing metal oxide. More particularly, the present invention relates to a sputtering process for depositing indium tin oxide (ITO) and a method of forming an ITO layer.

2. Description of Related Art

Generally speaking, the ITO layer has such advantages as good conductivity characteristics, high penetration for visible lights and high reflectivity for infrared lights, and is thus extensively applied in various electronic, optical and electro-optical apparatuses. The conventional process for manufacturing the ITO layer includes the vacuum evaporation method, the sputtering method and the chemical vapor deposition (CVD) method etc.

In the sputtering method, the process of fabricating the ITO layer comprises the following steps. First, a substrate is moved to a reaction chamber, where an ITO target is disposed. Next, plasma gas and moisture are conducted to the reaction chamber to form an ITO layer on the substrate. More specifically, the moisture conducted to the reaction chamber would be ionized into hydrogen ions and oxygen ions. And then the hydrogen ions would participate in the deposition process of the ITO such that the film deposited on the substrate becomes an amorphous ITO layer. Compared with the poly-crystalline ITO layer, which requires aqua regia for an etching processes, the amorphous ITO layer only requires a weak acid. Hence, the amorphous ITO layer which only requires a weak acid for an etching process can reduce the cost of etchant and subsequent process.

As mentioned, the moisture required during the sputtering process is provided from a moisture supplying equipment, which supplies the moisture to the reaction chamber. More specifically, the moisture supplying equipment comprises a water bottle and a mass flow controller (MFC), wherein the MFC is connected with the water bottle and the reaction chamber through pipes. Because the gas pressure within the water bottle is higher than that within the reaction chamber, the moisture in the water bottle would flow toward the reaction chamber. Meanwhile, the MFC can control the flow rate of the moisture entering the reaction chamber.

It should be noted that, during the gap between two complete processes, the MFC is closed. As a result, the moisture left in the pipes is condensed on the inner wall of the pipes to block the flow of moisture. Hence, when the moisture is required in the reaction chamber in subsequent process, the flow rate of moisture into the reaction chamber would be unstable, thus affecting the quality of the deposited ITO layer. In addition, in order to solve the unstable flow rate of the moisture, the equipment must be stopped to clean up the condensed moisture on the inner wall of the pipes. After the maintenance, the gas in the reaction chamber must be extracted until the reaction chamber is in vacuum for other inspection process. Therefore, the time required for the sputtering process and the manufacturing cost will increase.

### SUMMARY OF THE INVENTION

Accordingly, the present invention is directed to a sputtering process for depositing ITO, to replace the conventional sputtering process utilizing moisture as the reaction gas.

Accordingly, the present invention is also directed to a method of forming an ITO layer where an amorphous ITO layer is deposited without problems deriving from moisture in a conventional sputtering process.

According to an embodiment of the present invention, a sputtering process for depositing indium tin oxide (ITO) is disclosed. The sputtering process for depositing ITO comprises the following steps. First, a substrate is moved to a reaction chamber, wherein the reaction chamber comprises an ITO target disposed therein. Next, a plasma gas and a reaction gas are conducted into the reaction chamber to deposit an ITO layer on the substrate, wherein the reaction gas comprises at least a hydrogen gas having a volume ratio of 1%˜4% based on the total gas volume in the reaction chamber.

According to an embodiment of the present invention, the step of depositing the amorphous ITO layer onto the substrate comprises setting a direct-current electric power from 2.4 KW˜4.0 KW.

According to an embodiment of the present invention, a method of forming indium tin oxide (ITO) layer is disclosed. The method of forming ITO layer comprises the following steps. First, a substrate is moved into a reaction chamber, wherein the reaction chamber comprises an ITO target disposed therein. Next, a plasma gas and a reaction gas are conducted into the reaction chamber to deposit an amorphous ITO layer on the substrate, wherein the reaction gas comprises at least a hydrogen gas having a volume ratio of 1%˜4% based on the total gas volume in the reaction chamber. And then, the amorphous ITO layer is transformed into a polycrystalline ITO layer.

According to an embodiment of the present invention, the flow rate of the hydrogen gas is from 1 sccm˜4 sccm.

According to an embodiment of the present invention, the reaction gas further comprises an oxygen gas with a flow rate from 1 sccm˜3 sccm.

According to an embodiment of the present invention, the flow rate of the plasma gas is from 96 sccm˜99 sccm, and the plasma gas is an argon gas, for example.

According to an embodiment of the present invention, the pressure within the reaction chamber is from 0.15 pa˜0.88 pa.

According to an embodiment of the present invention, the step of depositing the amorphous ITO layer onto the substrate comprises setting a direct-current electric power from 2.4 KW˜4.0 KW.

According to an embodiment of the present invention, the step of transforming the amorphous ITO layer into a polycrystalline ITO layer comprises a thermal process.

According to an embodiment of the present invention, after depositing the amorphous ITO layer on the substrate and before transforming the amorphous ITO layer into a polycrystalline ITO layer, the method comprises performing a patterning process on the amorphous ITO layer.

According to the present invention, in the sputtering process for depositing ITO, the hydrogen gas is used as the reaction gas to replace the moisture used in the conventional sputtering process. Hence, the sputtering process for depositing ITO of the present invention would not have problems deriving from using moisture in the conventional method, and the quality of deposited ITO is close to that of the conventional sputtering process.

In addition, according to the present invention, an amorphous ITO layer is deposited, and a weak acid can be used for etching the amorphous ITO layer.

### BRIEF DESCRIPTION OF THE DRAWINGS

FIG. 1 schematically shows a sputtering process for depositing ITO according to one embodiment of the present invention.

FIG. 2 is a relationship diagram between a surface resistance and a uniformity of surface resistance of an annealed ITO formed in a sputtering process according to one embodiment of the present invention.

FIG. 3 is a relationship diagram between a surface resistance and a uniformity of surface resistance of an annealed ITO formed in a sputtering process according to another embodiment of the present invention.

FIGS. 4A to 4B schematically show the method of forming an ITO layer deposited in the sputtering process according to one embodiment of the present invention.

### DESCRIPTION OF THE EMBODIMENTS

Various specific embodiments of the present invention are disclosed below, illustrating examples of various possible implementations of the concepts of the present invention. The following description is made for the purpose of illustrating the general principles of the invention and should not be taken in a limiting sense. The scope of the invention is best determined by reference to the appended claims.

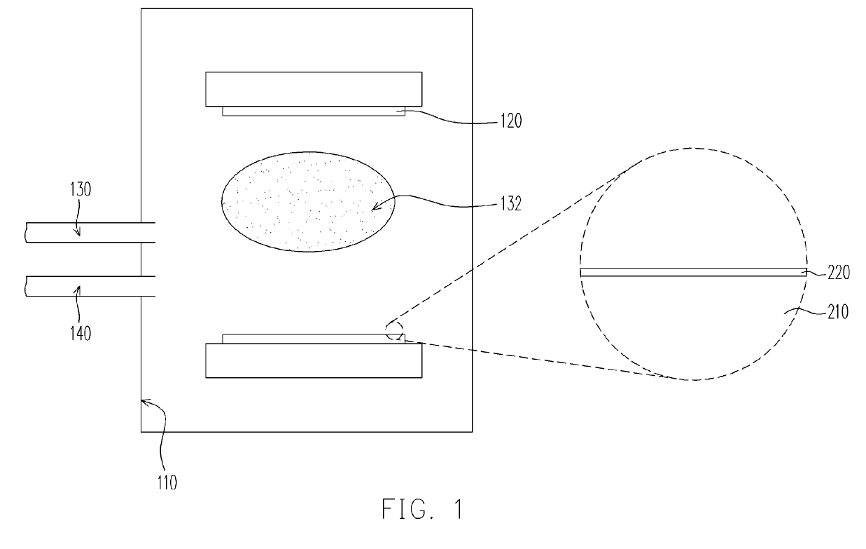

FIG. 1 schematically shows a sputtering process for depositing ITO according to one embodiment of the present invention. Referring to FIG. 1, the sputtering process for depositing ITO of the present invention comprises the following steps. First, a substrate 210 is moved into a reaction chamber 110 for a sputtering apparatus, wherein the reaction chamber 110 comprises an ITO target 120 disposed therein. The substrate 210 is a transparent substrate, a thin film transistor (TFT) array substrate of the liquid crystal display or a substrate covered with other films, for example.

And then, a plasma gas 130 and a reaction gas 140 are conducted into the reaction chamber 110 to form an ITO layer 220 on the substrate 210 (as shown in the magnified picture in FIG. 1), while a plasma 132 is formed between the substrate 210 and the ITO target 120. The plasma gas 130 is an inert gas, such as argon, helium and etc. It should be noted that the reaction gas 140 comprises at least a hydrogen gas, which has a volume ratio of 1%˜4% based on the total gas volume in the reaction chamber 110.

Compared with the conventional sputtering process of dissociating the molecules of the moisture into hydrogen ions, the sputtering process of the present invention can provide the required hydrogen ions by directly offering the hydrogen gas. The followings are a plurality of examples to illustrate the material characteristic of the ITO deposited in the sputtering process of the present invention.

TABLE 1

| | Direct- | | | |
|---|---|---|---|---|
| | current(DC) | Flow rate of | Flow rate of | Flow rate of |
| | Power(KW) | Argon(sccm) | Helium(sccm) | Oxygen(sccm) |
| Example 1 | 3.2 | 96 | 3 | 1 |
| Example 2 | 3.2 | 96 | 3 | 1 |
| Example 3 | 2.8 | 96 | 3 | 1 |
| Example 4 | 2.8 | 96 | 3 | 1 |
| Example 5 | 2.6 | 96 | 3 | 1 |
| Example 6 | 2.6 | 96 | 3 | 1 |
| Example 7 | 2.4 | 96 | 3 | 1 |
| Example 8 | 2.4 | 96 | 3 | 1 |

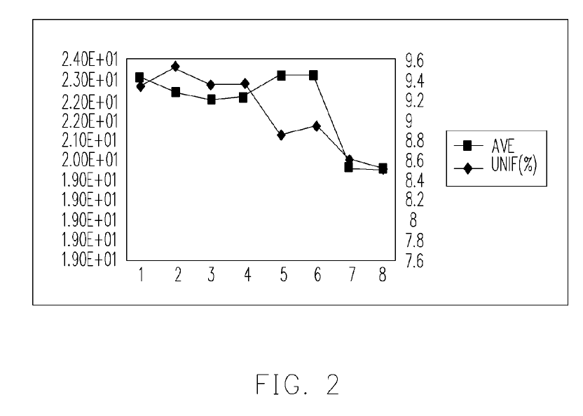

FIG. 2 is a relationship diagram between the surface resistance and the surface resistance uniformity of an annealed ITO. Referring to FIG. 2, the left side of the longitudinal coordinate represents a surface resistance of ITO, the right side of the longitudinal coordinate represents the surface resistance uniformity of ITO, and the horizontal coordinate represents the number of each example. The diagram drawn in FIG. 2 uses the measured figures according to the manufacturing parameter set in the sputtering process in Table 1.

Referring to FIG. 2, the surface resistance of most examples is around 20.7 ohm˜21.8 ohm, wherein the surface resistance of the examples 7 and 8 utilizing the 2.4 KW DC power has the lowest surface resistance. Noticeably, the reaction gas is not limited to a hydrogen gas and an oxygen gas, but the oxygen gas can improve the electrical quality of the deposited ITO.

TABLE 2

| | Direct- | | | Flow rate of |
|---|---|---|---|---|
| | current(DC) | Flow rate of | Flow rate of | Oxygen |
| | Power(KW) | Argon(sccm) | Helium(sccm) | (sccm) |
| Example 9 | 3.2 | 96 | 4 | 3 |
| Example 10 | 3.2 | 96 | 4 | 3 |
| Example 11 | 2.8 | 96 | 4 | 3 |
| Example 12 | 2.8 | 96 | 4 | 3 |
| Example 13 | 2.6 | 96 | 4 | 3 |
| Example 14 | 2.6 | 96 | 4 | 3 |
| Example 15 | 2.4 | 96 | 4 | 3 |
| Example 16 | 2.4 | 96 | 4 | 3 |

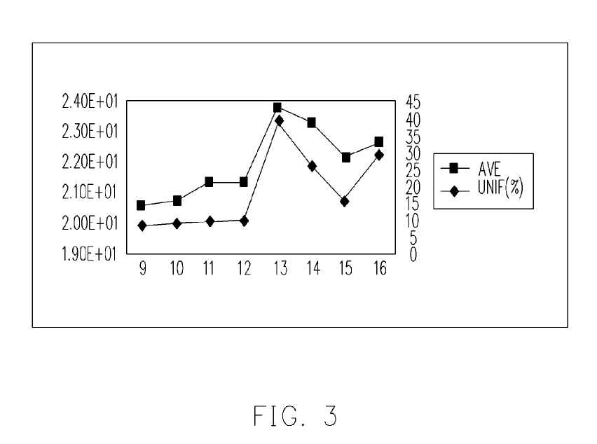

FIG. 3 is a relationship diagram between the surface resistance and the surface resistance uniformity of an annealed ITO according to another embodiment of the present invention. Referring to FIG. 3, the left side of the longitudinal coordinate represents surface resistance of ITO, the right side of the longitudinal coordinate represents the surface resistance uniformity of ITO, and the horizontal coordinate is the number of each example. The diagram drawn in FIG. 3 uses measured figures according to the manufacturing parameter set in the sputtering process in Table 2.

Referring to FIG. 3, the surface resistance of each example is from 20.5 ohm˜23.8 ohm, wherein the surface resistance of the examples 9 and 10 utilizing the 3.2 KW DC power has the lowest surface resistance.

From FIGS. 2 and 3, it can be concluded that the ITO layer can be fabricated under the following manufacturing condition: the flow rate of the hydrogen gas is from 1 sccm˜4 sccm (preferably, 3 sccm˜4 sccm), the flow rate of the argon gas is from 96 sccm˜99 sccm (preferably, 96 sccm), the flow rate of the oxygen gas is from 1 sccm˜3 sccm, and the DC power is from 2.4 KW˜4.0 KW (preferably, 2.4 KW˜3.2 KW).

In addition, referring to FIG. 2, the DC power is 2.4 KW, the flow rate of argon is 96 sccm, the flow rate of hydrogen is 3 sccm. Referring to FIG. 3, the DC power is 3.2 KW, the flow rate of argon is 96 sccm, the flow rate of hydrogen is 4 sccm. Under these conditions, a better ITO layer can be formed. The ITO layer fabricated utilizing the above-mentioned parameter is discussed in the following.

TABLE 3

| | | Flow rate | Flow rate | | Surface | |
|---|---|---|---|---|---|---|
| | Direct- | of | of | Pres- | resis- | |
| | current(DC) | Argon | Hydrogen | sure | tance | Residue |
| | Power(KW) | (sccm) | (sccm) | (pa) | (ohm) | of ITO |
| Exam- | 3.2 | 96 | 3 | 0.34 | 27.19 | YES |
| ple 17 | | | | | | |
| Exam- | 3.2 | 96 | 3 | 0.34 | 32.5 | YES |
| ple 18 | | | | | | |
| Exam- | 2.4 | 96 | 3 | 0.21 | 15.76 | NO |
| ple 19 | | | | | | |
| Exam- | 2.4 | 96 | 3 | 0.21 | 15.76 | NO |
| ple 20 | | | | | | |

If there is residue of ITO, a weak acid is used for an etching process, to see whether the ITO layer is fully etched. If the ITO layer is a polycrystalline structure, a weak acid can not completely etch the ITO layer. Referring to Table 3, the deposited ITO layer formed at 3.2 KW DC power and 96 sccm flow rate of argon has a polycrystalline area, which can not be etched by the weak acid fully. On the contrary, an amorphous ITO layer can be formed at 2.4 KW DC power and 96 sccm flow rate of argon, which can be etched by a weak acid, according to the present invention. In addition, the pressure within the reaction chamber 110 is set from 0.15 pa˜0.88 pa (preferably, from 0.21 pa˜0.34 pa).

With reference to the aforementioned experimental data, in the sputtering process of the present invention, an ITO layer, more specifically, an amorphous ITO layer can be formed, which can be etched by the weak acid. The method of depositing the ITO layer in the conventional sputtering process and that in the present invention are compared in the following (as shown in Table 4).

TABLE 4

| | | | Unifor- | | | |
|---|---|---|---|---|---|---|
| | | Unifor- | mity of | Crys- | Contact | Amount |
| | | mity of | film | talline | resis- | of |
| | Transpar- | etching | thickness | Sub- | tance | foreign |
| | ency (%) | (%) | (%) | stance | (ohm) | bodies |
| Example | 91 | 12.1 | 3 | none | 2˜3 | 100 |
| 21 (the | | | | | | |
| present | | | | | | |
| inven- | | | | | | |
| tion) | | | | | | |
| Example | 92 | 13.6 | 4.1 | none | 2˜5 | 300 |
| 22(con- | | | | | | |
| ven- | | | | | | |
| tional | | | | | | |
| skill) | | | | | | |

Referring to Table 4, the example 21 is the ITO layer utilizing the sputtering process of the present invention, and the example 22 is the ITO layer utilizing the conventional sputtering process with the moisture. It can be seen that the ITO layer using the sputtering process of the present invention has the desired quality as the ITO layer deposited in the conventional sputtering process, and with fewer foreign bodies, wherein the amount of foreign bodies is measured before the ITO layer is cleaned. In addition, the sputtering process for depositing the ITO layer of the present invention has no problems deriving from using the moisture during the conventional sputtering process.

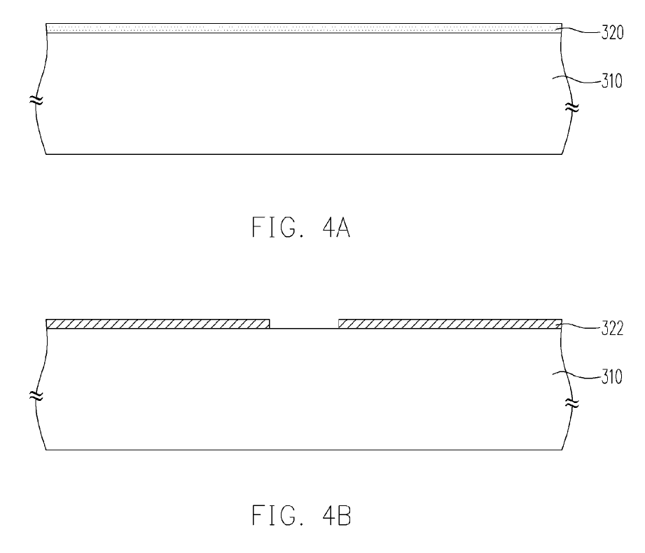

FIGS. 4A to 4B schematically show the method of forming an ITO layer deposited in the sputtering process according to one embodiment of the present invention. Referring to FIG. 4A, an amorphous ITO layer 320 is formed on a substrate 310. More specifically, the substrate 310 is moved into a reaction chamber, wherein the reaction chamber comprises an ITO target disposed therein. Next, a plasma and a reaction gas are conducted into the reaction chamber, wherein the reaction gas comprises at least a hydrogen gas having a volume ratio of 1%˜4% based on the total gas volume in the reaction chamber (similar to FIG. 1).

In order to promote the electrical quality of the ITO layer, the amorphous ITO layer 320 is transformed into a polycrystalline ITO layer 322 in a thermal process or other annealing process, for example. In addition, after the amorphous ITO layer 320 is formed on the substrate 310, a patterning process is performed on the amorphous ITO layer 320, where a weak acid is used for the etching process.

In conclusion, the sputtering process for depositing ITO layer of the present invention utilizes the hydrogen gas as the reaction gas instead of the moisture in the conventional sputtering process to fabricate the amorphous layer, which can be etched by the relatively cheaper weak acid.

Compared with the conventional sputtering process, the sputtering process for depositing ITO layer of the present invention can not only utilize the cheaper weak acid for the etching process, but also prevent the problems deriving from using moisture in the conventional sputtering process.

The above description provides a full and complete description of the embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A sputtering process for depositing indium tin oxide (ITO), the sputtering process comprising:
moving a substrate into a reaction chamber, wherein the reaction chamber comprises an ITO target disposed therein; and
providing a plasma gas and a reaction gas into the reaction chamber to deposit an ITO layer on the substrate, wherein the reaction gas comprises at least a hydrogen gas having a volume ratio of 1%˜4% based on the total gas volume in the reaction chamber.

2. The sputtering process for depositing indium tin oxide of claim 1, wherein the flow rate of the hydrogen gas is from 1 sccm˜4 sccm.

3. The sputtering process for depositing indium tin oxide of claim 1, wherein the reaction gas further comprises oxygen.

4. The sputtering process for depositing indium tin oxide of claim 3, wherein the flow rate of the oxygen is from 1 sccm˜3 sccm.

5. The sputtering process for depositing indium tin oxide of claim 1, wherein the flow rate of the plasma gas is from 96 sccm˜99 sccm.

6. The sputtering process for depositing indium tin oxide of claim 5, wherein the plasma gas comprises argon gas.

7. The sputtering process for depositing indium tin oxide of claim 1, wherein the pressure within the reaction chamber is from 0.15 pa˜0.88 pa.

8. The sputtering process for depositing indium tin oxide of claim 1, wherein the step of depositing the ITO layer onto the substrate comprises setting a direct-current electric power from 2.4 KW˜4.0 KW.

9. A method of forming indium tin oxide (ITO) layer, the method comprising:
moving a substrate into a reaction chamber, wherein the reaction chamber comprises an ITO target disposed therein;
providing a plasma gas and a reaction gas into the reaction chamber to deposit an amorphous ITO layer on the substrate, wherein the reaction gas comprises at least a hydrogen gas having a volume ratio of 1%˜4% based on the total gas volume in the reaction chamber; and
transforming the amorphous ITO layer into a polycrystalline ITO layer.

10. The method of forming indium tin oxide layer of claim 9, wherein the flow rate of the hydrogen gas is from 1 sccm˜4 sccm.

11. The method of forming indium tin oxide layer of claim 9, wherein the reaction gas further comprises oxygen.

12. The method of forming indium tin oxide layer of claim 11, wherein the flow rate of the oxygen is from 1 sccm˜3 sccm.

13. The method of forming indium tin oxide layer of claim 9, wherein the flow rate of the plasma gas is from 96 sccm˜99 sccm.

14. The method of forming indium tin oxide layer of claim 9, wherein the plasma gas comprises argon gas.

15. The method of forming indium tin oxide layer of claim 9, wherein the pressure within the reaction chamber is set from 0.15 pa˜0.88 pa.

16. The method of forming indium tin oxide layer of claim 9, wherein the step of depositing the amorphous ITO layer onto the substrate comprises setting a direct-current electric power from 2.4 KW˜4.0 KW.

17. The method of forming indium tin oxide layer of claim 9, wherein the step of transforming the amorphous ITO layer into a polycrystalline ITO layer comprises a thermal process.

18. The method of forming indium tin oxide layer of claim 9, further comprising a step of patterning the amorphous ITO layer after depositing the amorphous ITO layer on the substrate and before transforming the amorphous ITO layer into the polycrystalline ITO layer.
